(19) United States
(12) Patent Application Publication
(10) Pub. No.: US 2007/0029572 A1
(43) Pub. Date: Feb. 8, 2007

(54) LED having improved soldering structure, method for soldering the LED to PCB, and LED assembly manufactured by the method

(75) Inventors: Kyung Taeg Han, Suwon (KR); Seon Goo Lee, Gunpo (KR); Hun Joo Hahm, Sungnam (KR); Seong Yeon Han, Suwon (KR); Chang Ho Song, Seoul (KR); Young Sam Park, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/497,233

(22) Filed: Aug. 2, 2006

(30) Foreign Application Priority Data
Aug. 2, 2005 (KR) 10-2005-0070805

(51) Int. Cl. H01L 33/00; H01L 21/00

(52) U.S. Cl. 257/99; 257/100; 438/27; 257/E33.066; 257/E33.058

(57) ABSTRACT

The invention relates to an LED with an improved soldering structure, a method of assembling the LED to a PCB, and an LED assembly manufactured by the method. The LED includes an LED chip and a pair of leads with an end electrically connected the LED chip and the other end to be connected to an external power source, having a hole or a cutout part formed therein. The LED also includes a package body housing a part of the lead in the side of the LED chip, and a transparent lens placed on a surface of the package body in the side of the LED chip, for emitting light laterally. This improves soldering conditions for soldering with the other end of the lead placed on the solder, saving the amount of a solder paste while enhancing bonding strength after soldering.

### CLAIM OF PRIORITY

This application claims the benefit of Korean Patent Application No. 2005-70805 filed on Aug. 2, 2005, in the Korean Intellectual Property Office, the disclosure of which is incorporated herein by reference.

### BACKGROUND OF THE INVENTION

1. Field of the Invention

The present invention relates to a light emitting diode (LED), and more particularly, to an LED having an improved soldering structure in which a hole/cutout part is formed in an external terminal portion of a lead to improve soldering conditions, thereby saving the amount of solder paste used and enhancing the bonding strength after soldering, to a method of assembling the LED to a printed circuit board (PCB) via soldering, and to an LED assembly manufactured by the assembling method.

2. Description of the Related Art

In general, a light emitting diode (LED) is a semiconductor device for generating various colors of light when current is applied. The color of light generated from the LED is mainly determined by chemical substances constituting a semiconductor chip of the LED. Such an LED has numerous merits such as a long lifetime, low power, good initial operation characteristics, high vibration resistance and high tolerance for repeated power regulation, and thus its demand is steadily increasing.

FIG. 1 illustrates an example of an LED according to the prior art.

In the LED 1, an LED chip (not shown) is mounted in a package body 10, and a pair of leads 30 is partially housed in the package body 10 while supplying external power to the LED chip electrically connected thereto. In addition, a cover or a lens 20 made of transparent material is placed on an upper part of the package body 10 to protect the LED chip from the external environment while laterally emitting the light generated from the LED chip. Therefore, this type of LED 1 is also called a side view LED.

Such an LED is typically mounted on a printed circuit board such as a metal core printed circuit board (MCPCB) to be used in a form of an LED assembly. In order for this, a plurality of external terminals of the LED should be electrically connected and fixed to wires or circuit patterns on a surface of the printed circuit board, which is carried out typically by a reflow process or soldering.

Among these, the reflow process is restricted by the material of the LED, or more specifically the material of the lens or cover. In particular, in the case of the side view LED 1 shown in FIG. 1, the lens 20 is fabricated with a material sensitive to heat. This is because a material that is resistant to heat has low moldability, and thus is not desirable for precisely forming the complex shape of the lens 20. Therefore, it is difficult to mount the side view LED 1 shown in FIG. 1 in a high-temperature condition such as in the reflow process.

An example of soldering procedures for mounting the above described LED 1 on a metal PCB 40 will now be explained with reference to FIGS. 2 and 3.

In such soldering procedures, a predetermined amount of a solder paste 50 is dispensed on a circuit pattern 42 which is to be connected to the lead 30 of the LED 1. Then LED 1 is seated on the metal PCB 40 such that the lead 30 is placed over the dispensed solder paste 50. Next, a tip 62 of a soldering iron 60 in a form of a bar, also called a “hot bar” is made to contact an upper surface of the lead 30. Thereby, the solder paste 50 melts by the heat of the soldering iron 60, and then cools down and solidifies to bond the lead 30 to the circuit pattern 42 underneath.

Through these soldering procedures, the LED 1 is mounted on the printed circuit board 40 as shown in FIG. 4. A structure in which the LED 1 is mounted on the printed circuit board 40 as described above is called an LED assembly.

However, the conventional LED 1 and soldering procedures using the same have following problems.

As the circuit pattern 42, the solder paste 50 and the lead 30 are stacked in their order from the bottom, the tip 62 of the soldering iron 60 contacts only the lead 30 and does not directly contact the solder paste 50. Thus, heat is transferred from the soldering iron 60 through the lead 30 to the solder paste 50.

Therefore, the temperature of the soldering iron 60 should be controlled high to obtain heat needed for melting the solder paste 50. Generally, the soldering iron 60 is heated at about 300° C. or higher, which however is not desirable as the heat of the soldering iron 60 may be transferred to the LED 1 to expose the LED 1 and especially the lens 20 to the high-temperature environment.

In addition, after the soldering, the solder paste 50 exists only between the circuit pattern 42 and the lead 30 or surrounds a lower edge of the lead 30 as shown in FIG. 4. Thus, the bonding strength between the lead 30 and the circuit pattern 42 by the solder paste 50 is weak.

In particular, in case when the lead 30 is warped upward, even if the soldering is conducted with the soldering iron 60 pressing down the lead 30, the lead 30 may warp upward again before the solder paste 50 solidifies. In this case, not only the bonding strength between the lead 30 and the circuit pattern 42 significantly decreases but also the electric connection between the two may be severed.

### SUMMARY OF THE INVENTION

The present invention has been made to solve the foregoing problems of the prior art and therefore an object of certain embodiments of the present invention is to provide an LED having an improved soldering structure in which a hole/cutout part is formed in an external terminal portion of a lead for soldering, thereby improving soldering conditions while saving the amount of solder paste, a method of assembling the LED to a printed circuit board (PCB) via soldering, and an LED assembly manufactured by the assembling method.

Another object of certain embodiments of the invention is to provide an LED having an improved soldering structure in which a hole/cutout part for soldering is formed in an external terminal portion of a lead to increase bonding strength after the soldering, a method of assembling the LED to a printed circuit board (PCB), and an LED assembly manufactured by the assembling method.

According to an aspect of the invention for realizing the object, there is provided a side view LED including: an LED chip; a pair of leads with an end electrically connected the LED chip and the other end to be connected to an external power source, the other end having a hole or a cutout part formed therein; a package body housing a part of the lead in the side of the LED chip; and a transparent lens placed on a surface of the package body in the side of the LED chip, the lens configured to emit light laterally.

In the LED according to the invention, the hole or the cutout part has a dimension large enough for receiving a tip of a soldering iron used in soldering procedures for mounting the LED to a printed circuit board.

According to another aspect of the invention for realizing the object, there is provided a method for assembling a side view LED to a printed circuit board including steps of:

(i) dispensing a predetermined amount of a solder paste on a circuit pattern of a printed circuit board;

(ii) seating the LED described in claim 1 on the printed circuit board such that an end of the lead is placed on the dispensed solder paste;

(iii) placing a tip of a soldering iron pre-heated at a predetermined temperature in a hole or a cutout part of the lead; and

(iv) removing the soldering iron after an elapse of a predetermined time to solidify the melted solder paste.

According to the method for assembling the LED of the present invention, the step (ii) comprises pressing down the lead at such a level of strength that a portion of solder paste flows onto an upper surface of the lead through the hole or the cutout part.

According to the method for assembling the LED of the present invention, the step (iii) comprises placing the tip of the soldering iron inside the hole or the cutout part of the lead.

According to the method for assembling the LED of the present invention, the step (iii) comprises using the hole or the cutout part of the lead as a guide.

According to the method for assembling the LED of the present invention, the step (iv) comprises gradually removing the soldering iron to allow the solder paste to flow through the hole or the cutout part of the lead in contact with the tip of the soldering iron.

According to yet another aspect of the invention for realizing the object, there is provided an LED assembly including: a printed circuit board with a circuit pattern formed on a surface thereof; and an LED assembled with the printed circuit board by the aforedescribed assembling method.

In the LED assembly of the present invention, a portion of the solidified solder paste is inside the hole or the cutout part of the lead.

In the LED assembly of the present invention, a portion of the solidified solder paste is on an upper surface of the lead, thereby forming a rivet structure for holding the lead together with the solidified portion inside the hole or the cutout part.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view illustrating a conventional LED;

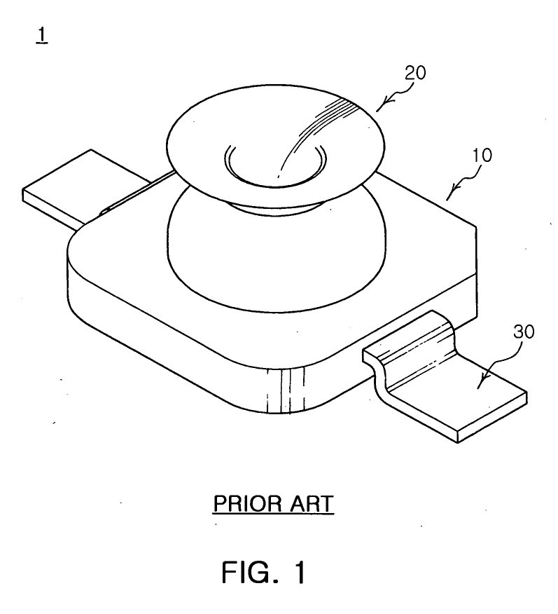

FIG. 2 is a perspective view illustrating soldering procedures of the conventional LED;

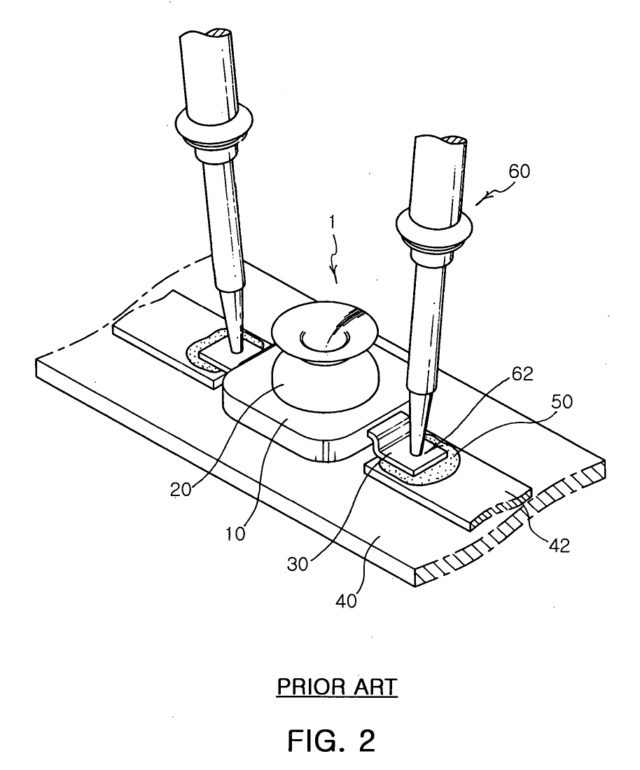

FIG. 3 is a front view of a part of FIG. 2;

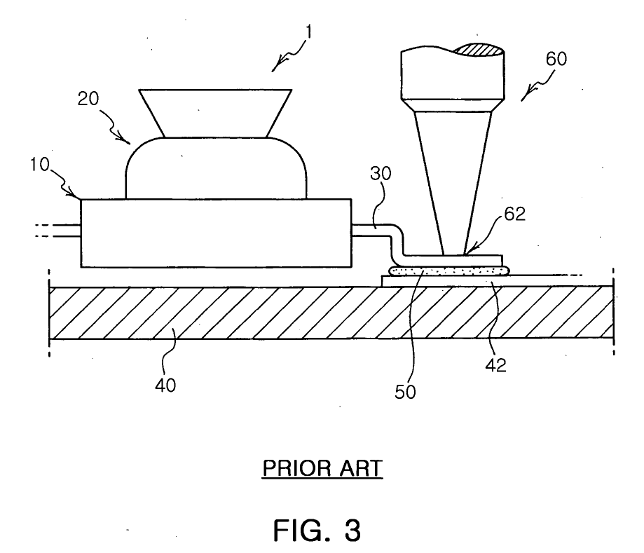

FIG. 4 is a front view illustrating an LED assembly manufactured by the conventional soldering procedures;

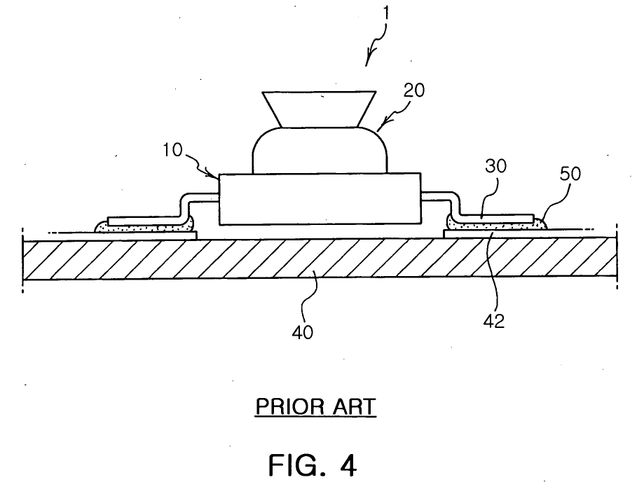

FIG. 5 is a perspective view illustrating an LED having an improved soldering structure according to the present invention;

FIG. 6 is a plan view illustrating an initial step of soldering procedures of the LED according to the present invention;

FIG. 7 is a sectional view taken along line 7-7 of FIG. 6;

FIG. 8 is a sectional view taken along line 8-8 of FIG. 6;

FIG. 9 is a perspective view illustrating a subsequent step after the initial step of FIG. 6 of the soldering procedures of the LED according to the present invention;

FIG. 10 is a front view of FIG. 9;

FIG. 11 is a front view illustrating an LED assembly manufactured by the soldering procedures according to the present invention;

FIG. 12 is a front view illustrating a step corresponding to the step of FIG. 10 according to another embodiment of the present invention; and

FIG. 13 is a plan view illustrating variations of improved soldering structures of the LED according to another embodiment of the present invention.

### DETAILED DESCRIPTION OF THE PREFERRED EMBODIMENT

Preferred embodiments of the present invention will now be described in detail with reference to the accompanying drawings.

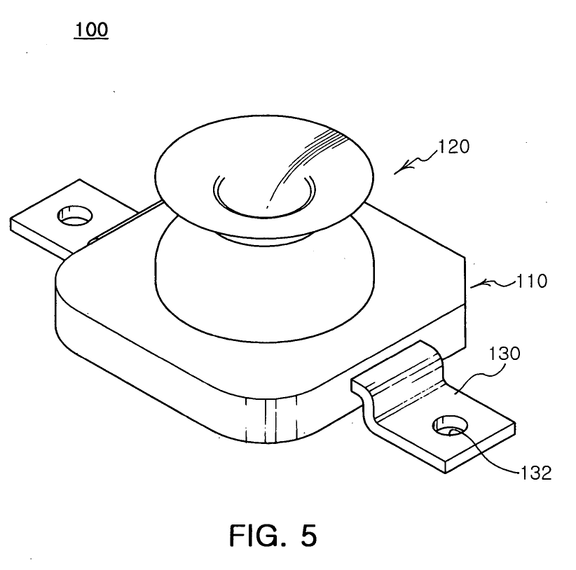

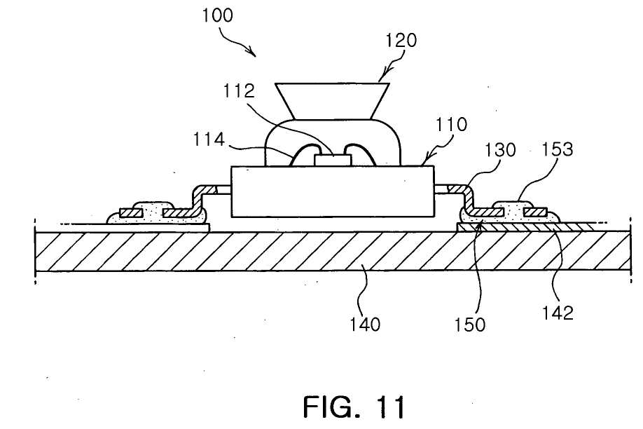

Referring to FIG. 5, a side view LED 100 according to the present invention includes a package body 110 with an LED chip 112 (see FIG. 11) mounted therein, a pair of leads 130 partially housed in the package body 110 and electrically connected to the LED chip to supply an external power and a transparent cover or lens 120 placed on an upper part of the package body 110 to protect the LED chip from an external environment and to laterally emit the light from the LED chip. In addition, an external terminal portion of the lead 130 has a hole 132 perforated therein.

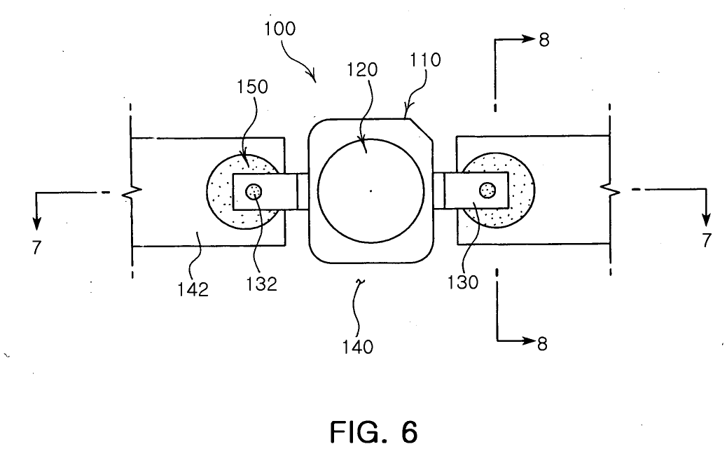

Now, mounting procedures for mounting the LED 100 according to the present invention to a printed circuit board 140 such as a metal printed circuit board will be explained with reference to FIGS. 6 to 11.

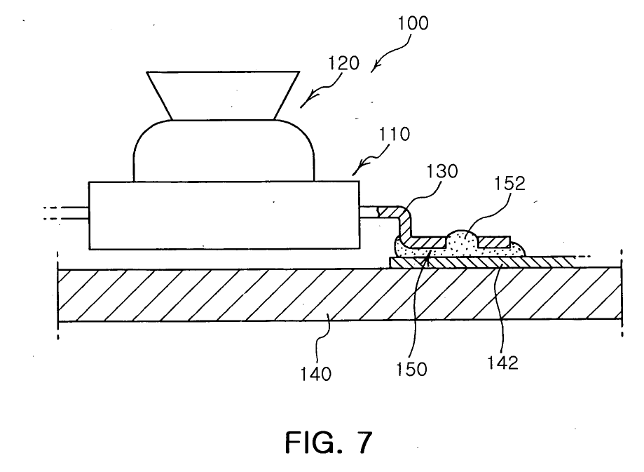

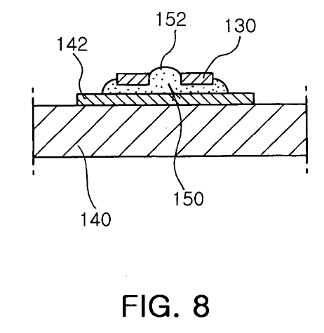

First, as shown in FIGS. 6 to 8, a predetermined amount of solder paste 150 is dispensed on a circuit pattern 140 of a printed circuit board 140. Then, the LED 100 is seated on the printed circuit board 140 such that the lead 130 is placed on the dispensed solder paste 150. In this way, having fluidity, some portion of the solder paste 150 flows over through the hole of the lead 130. Especially when the LED 100 is seated and pressed a bit, a solder protuberance 152 is formed as shown in FIGS. 7 and 8.

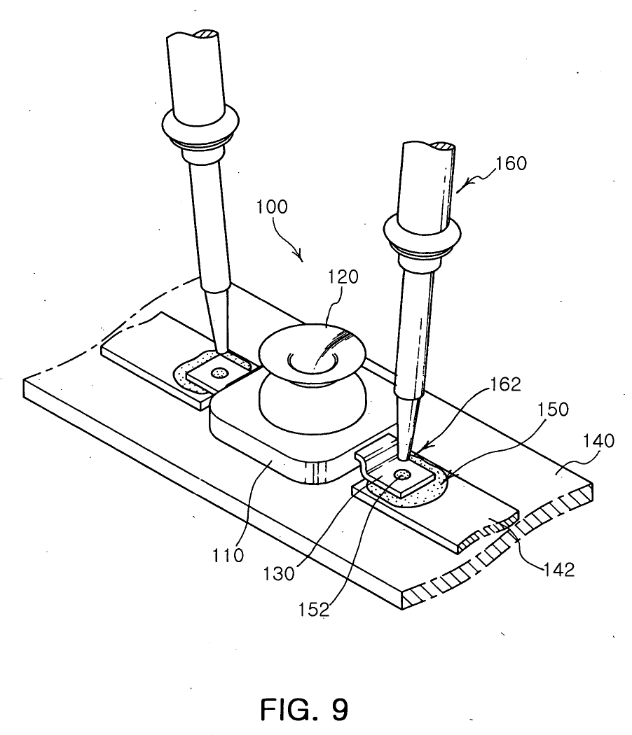

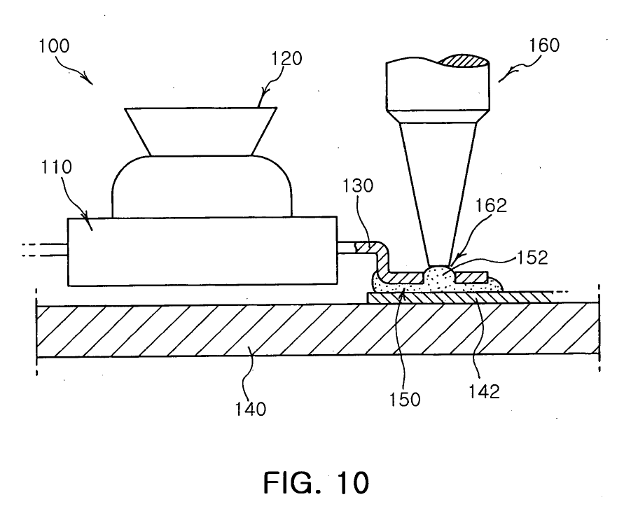

Next, as shown in FIGS. 9 and 10, a soldering iron 160 in a form of a pair of bars, also called a “hot bar,” is used to heat the solder paste 150. As shown in FIG. 10, as a tip 162 of the soldering iron 160 is placed on the solder protuberance 152, the solder paste 150 receives heat directly from the soldering iron 160 to melt quickly.

Thus, the time for soldering is shortened, and thus the possibility that the heat is transferred through the lead 130 to the LED 100, especially to the lens 120 is decreased. In addition, unlike the prior art, even if the temperature of the soldering iron 160 is lowered, the solder paste 150 can easily melt.

In addition, the melted solder paste 150 flows over through the hole 132 of the lead 130 to an upper surface of the lead 130, which has an effect of increasing the bonding strength between the lead 130 and the circuit pattern 142.

Moreover, the lead hole 132 of the lead may function as a guide through which the tip 162 of the soldering iron contacts the lead 130. That is, a position where the soldering iron 162 is to be applied can be exactly marked by the lead hole 132.

FIG. 11 illustrates an LED assembly obtained through the aforedescribed soldering procedures.

As shown in FIG. 11, a portion of the solder paste 150 flows through the hole 152 of the lead 130 and is solidified on an upper surface of the lead 130. As a result, the solder paste 150 forms a fastening part in a form of a rivet in its entirety for holding the lead 130, thus having a large contact area with the lead to increase the bonding strength with the lead 130.

With this structure, a stable bonding is formed between the lead 130 and the circuit pattern 142.

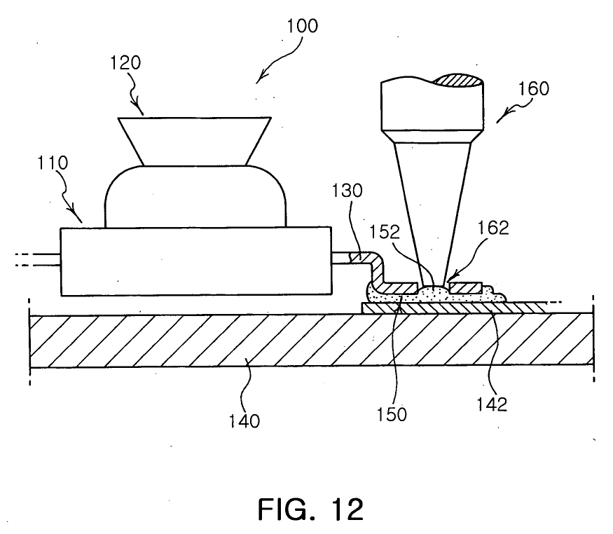

FIG. 12 illustrates another advantage of the present invention.

According to the present invention, the diameter of the lead hole 132 can be made larger than the diameter of the tip 162 of the soldering iron 160 so that even if the solder protuberance 152 is not protruded outside of the hole 132 of the lead 130, the tip 162 of the soldering iron 160 can be inserted into the lead hole 132 during the soldering procedures, thereby increasing the procedural efficiency.

In this case, the soldering iron 160 can be removed gradually out of the hole 132 to accelerate the flow of the melted solder paste upward through the hole 132 in contact with the tip 162 of the soldering iron.

In addition, the lead hole 130 may be smaller than the tip 162 of the soldering iron, and still can function well as a guide for soldering.

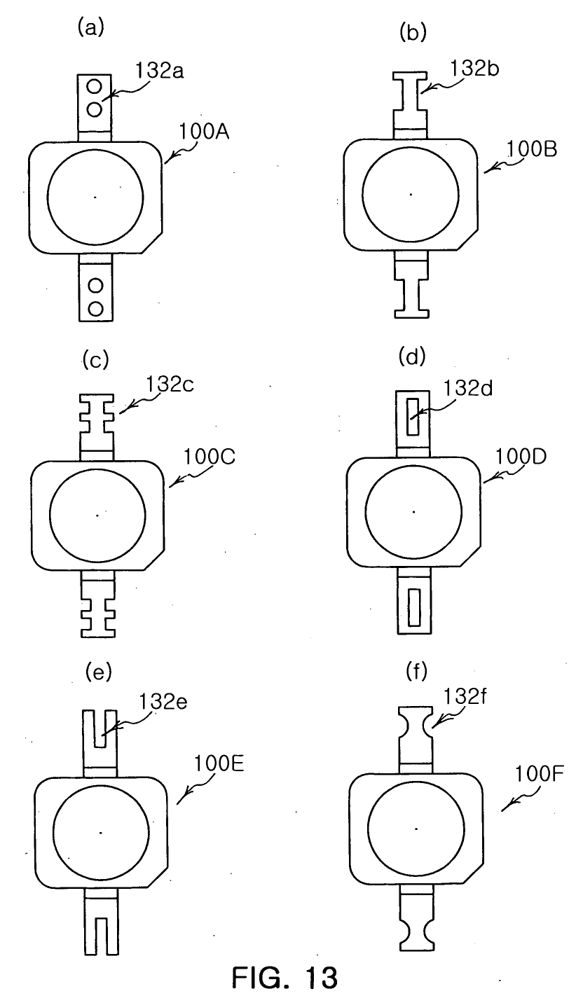

FIG. 13 is a plan view illustrating variations of the improved soldering structures according to the present invention.

That is, (a) shows an LED 100A with a pair of circular holes 132a formed in each lead, (b) and (c) show LEDs 100B and 100C with cutout edges 132b and 132c in opposed side portions of each lead. (d) shows an LED 100D with a slit or elongated hole 132d formed in each lead, and (e) shows an LED 100E having a long cutout part 132e formed from an end of the lead. In addition, (f) shows an LED 100F with semicircular cutout edges 132f formed on opposed side portions of each lead.

As shown, the LED according to certain embodiments of the present invention may have a variety of holes or cutout parts in external terminal portions of the leads to improve the soldering conditions and the bonding state after the soldering.

According to certain embodiments of the present invention set forth above, a hole/cutout part for soldering may be formed in an external terminal portion of a lead to improve soldering conditions and save the amount of solder paste. In addition, the solder paste fills up the hole/cutout part to increase the bonding strength after the soldering.

While the present invention has been shown and described in connection with the preferred embodiments, it will be apparent to those skilled in the art that modifications and variations can be made without departing from the spirit and scope of the invention as defined by the appended claims.

What is claimed is:

1. A side view LED comprising:
an LED chip;
a pair of leads with an end electrically connected the LED chip and the other end to be connected to an external power source, the other end having a hole or a cutout part formed therein;
a package body housing a part of the lead in the side of the LED chip; and
a transparent lens placed on a surface of the package body in the side of the LED chip, the lens configured to emit light laterally.

2. The side view LED according to claim 1, wherein the hole or the cutout part has a dimension large enough for receiving a tip of a soldering iron used in soldering procedures for mounting the LED to a printed circuit board.

3. A method for assembling a side view LED to a printed circuit board comprising steps of:
(i) dispensing a predetermined amount of a solder paste on a circuit pattern of a printed circuit board;
(ii) seating the LED described in claim 1 on the printed circuit board such that an end of the lead is placed on the dispensed solder paste;
(iii) placing a tip of a soldering iron pre-heated at a predetermined temperature in a hole or a cutout part of the lead; and
(iv) removing the soldering iron after an elapse of a predetermined time to solidify the melted solder paste.

4. The assembly method according to claim 3, wherein the step (ii) comprises pressing down the lead at such a level of strength that a portion of solder paste flows onto an upper surface of the lead through the hole or the cutout part.

5. The assembly method according to claim 3, wherein the step (iii) comprises placing the tip of the soldering iron inside the hole or the cutout part of the lead.

6. The assembly method according to claim 4, wherein the hole or the cutout part has such a dimension large enough for receiving a tip of a soldering iron used in soldering procedures for mounting the LED to a printed circuit board.

7. The assembly method according to claim 3, wherein the step (iii) comprises using the hole or the cutout part of the lead as a guide.

8. The assembly method according to claim 3, wherein the step (iv) comprises gradually removing the soldering iron to allow the solder paste to flow through the hole or the cutout part of the lead in contact with the tip of the soldering iron.

9. An LED assembly comprising:
a printed circuit board with a circuit pattern formed on a surface thereof; and
an LED assembled with the printed circuit board by the method described in claim 3.

10. The LED assembly according to claim 9, wherein a portion of the solidified solder paste is inside the hole or the cutout part of the lead.

11. The LED assembly according to claim 10, wherein a portion of the solidified solder paste is on an upper surface of the lead, thereby forming a rivet structure for holding the lead together with the solidified portion inside the hole or the cutout part.
